(19) United States
(12) Patent Application Publication
(10) Pub. No.: US 2023/0402993 A1
(43) Pub. Date: Dec. 14, 2023

(54) Film bulk acoustic wave resonator and preparation method thereof

(71) Applicant: Wuhan MEMSonics Technologies Co., Ltd., Wuhan (CN)

(72) Inventors: Chengliang SUN, Wuhan (CN); Yao CAI, Wuhan (CN); Bowoon SOON, Singapore (SG); Zhipeng DING, Singapore (SG); Binghui LIN, Wuhan (CN)

(21) Appl. No.: 18/205,016

(22) Filed: Jun. 2, 2023

(30) Foreign Application Priority Data
Jun. 8, 2022 (CN) 202210643790.X

(51) Int. Cl. H03H 9/17; H03H 3/02; H03H 9/02

(52) U.S. Cl. CPC H03H 9/173; H03H 3/02; H03H 9/02125; H03H 2003/021

(57) ABSTRACT

The present disclosure provides a film bulk acoustic wave resonator and a preparation method thereof, and relates to the technical field of semiconductors. The film bulk acoustic wave resonator includes a substrate and a bottom electrode, a piezoelectric layer and a top electrode which are located on an upper surface of the substrate, the bottom electrode is provided with a first arched part so as to form a first cavity between the first arched part and the substrate; and a first reflection cavity is formed between the bottom electrode and the piezoelectric layer and located in a slope of the first arched part, the bottom electrode is provided with the first arched part and the first reflection cavity may be located in an oblique plane of the slope of the first arched part.

### CROSS-REFERENCE TO RELATED APPLICATION

The present disclosure claims the benefit of priority of Chinese patent application No. CN202210643790.X, entitled “FILM BULK ACOUSTIC WAVE RESONATOR AND PREPARATION METHOD THEREOF”, filed to National Intellectual Property Administration on Jun. 28, 2022, the entire contents of which are incorporated herein by reference.

### TECHNICAL FIELD

The present disclosure relates to the technical field of semiconductors, and more particularly relates to a film bulk acoustic wave resonator and a preparation method thereof.

### BACKGROUND

A radio-frequency filter plays a crucial role in a radio frequency front-end module, and particularly in high-frequency communication, a filter based on a bulk acoustic wave resonator technology plays an important role due to its excellent performance. A film bulk acoustic wave filter has characters of high resonant frequency, complementary metal-oxide-semiconductor (CMOS) process compatibility, a high quality factor, low losses, a low temperature coefficient, high power carrying capacity, etc., thereby gradually replacing a surface acoustic wave resonator to become market mainstream. However, a radio-frequency resonator serves as a core device of the filter, which directly influences performance of the filter.

According to an existing film bulk acoustic wave resonator, a reflection cavity is commonly only designed in a top electrode, and is located in a periphery of an effective working area of the film bulk acoustic wave resonator, so as to reflect transverse acoustic waves, reduce a transverse parasitic mode and acoustic wave leakage, and improve the quality factor of the resonator. But, along with the development of a radio-frequency technique, there are higher requirements for the aspects of the transverse parasitic mode and the acoustic wave leakage of the resonator, which are difficult to satisfy in the existing film bulk acoustic wave resonator.

### SUMMARY

One aspect of an embodiment of the present disclosure provides a film bulk acoustic wave resonator, including a substrate and a bottom electrode, a piezoelectric layer and a top electrode which are located on an upper surface of the substrate. The bottom electrode is provided with a first arched part so as to form a first cavity between the first arched part and the substrate; and a first reflection cavity is formed between the bottom electrode and the piezoelectric layer and located in a slope of the first arched part.

In some embodiments, a recessed second cavity is formed in the upper surface of the substrate and communicates with the first cavity to form an air gap.

In some embodiments, the first reflection cavity is an annular cavity annularly formed in a periphery of an effective working area of the film bulk acoustic wave resonator; or the film bulk acoustic wave resonator includes a plurality of first reflection cavities not communicating with one another, which are distributed in the periphery of the effective working area of the film bulk acoustic wave resonator.

In some embodiments, the piezoelectric layer is provided with a second arched part stacked with the first arched part, and a second reflection cavity is formed between the second arched part and the top electrode, and located in the periphery of the effective working area of the film bulk acoustic wave resonator.

In some embodiments, the second reflection cavity is located in a slope of the second arched part.

In some embodiments, the top electrode is provided with a third arched part stacked with the second arched part, and all the first arched part, the second arched part and the third arched part are provided with flat tops parallel to the upper surface of the substrate.

In some embodiments, the second reflection cavity is located in the flat top of the second arched part.

In some embodiments, a thickness of the first cavity is less than a thickness of the second cavity.

In some embodiments, a thickness of the air gap ranges from 1 micron to 5 microns.

In some embodiments, the first reflection cavity includes a first-kind reflection cavity and a second-kind reflection cavity which are both located in the slope of the first arched part so as to reflect transverse acoustic waves.

In some embodiments, the first-kind reflection cavity does not communicate with the air gap.

In some embodiments, the second-kind reflection cavity communicates with the air gap.

In some embodiments, the second-kind reflection cavity does not communicate with the air gap.

In some embodiments, the second reflection cavity includes a third-kind reflection cavity formed in the slope of the second arched part.

In some embodiments, the top electrode is provided with the third arched part stacked with the second arched part, and all the first arched part, the second arched part and the third arched part are provided with the flat tops parallel to the upper surface of the substrate.

In some embodiments, the first arched part, the second arched part and the third arched part are sequentially stacked.

In some embodiments, the second reflection cavity further includes a fourth-kind reflection cavity formed in the flat top of the second arched part.

Another aspect of an embodiment of the present disclosure provides a preparation method of a film bulk acoustic wave resonator. The method includes: a substrate is provided and a recessed third cavity is formed in an upper surface of the substrate; a first sacrificial layer is formed on the upper surface of the substrate, which includes a first part filling into the third cavity and a second part located above the first part and higher than the upper surface of the substrate; a bottom electrode is formed on the upper surface of the substrate, which has a first arched part covering the second part; a second sacrificial layer is formed at a slope of the first arched part; a piezoelectric layer and a top electrode are sequentially formed on the bottom electrode; and the first sacrificial layer and the second sacrificial layer are released so as to respectively form an air gap between the bottom electrode and the substrate and a first reflection cavity, located at the slope of the first arched part, between the bottom electrode and the piezoelectric layer.

In some embodiments, the piezoelectric layer and the top electrode are sequentially formed on the bottom electrode includes: a third sacrificial layer is formed on the piezoelectric layer; the top electrode is formed covering the third sacrificial layer on the piezoelectric layer; and the third sacrificial layer is released so as to form a second reflection cavity between the piezoelectric layer and the top electrode, where the second reflection cavity is located in a periphery of an effective working area of the film bulk acoustic wave resonator.

In some embodiments, the first sacrificial layer is etched to form a groove, and the groove is located above the third cavity.

In some embodiments, the first reflection cavity comprises a first-kind reflection cavity and a second-kind reflection cavity which are both located in the slope of the first arched part so as to reflect transverse acoustic waves.

In some embodiments, the bottom electrode is deposited on the first sacrificial layer, and one end of the bottom electrode extends into the groove;
the second sacrificial layer is deposited and makes contact with the first sacrificial layer; and
the first sacrificial layer and the second sacrificial layer are released so that the second-kind reflection cavity can communicate with the lower air gap.

### BRIEF DESCRIPTION OF THE DRAWINGS

In order to describe technical schemes in the embodiments of the present disclosure more clearly, drawings required to be used in the embodiments will be simply introduced below, it is to be understood that the following drawings only show some embodiments of the present disclosure, which cannot be regarded as limitations on a scope, and those of ordinary skill in the art can further obtain other related drawings according to the drawings without creative work.

FIG. 1 is a schematic flowchart of a preparation method of a film bulk acoustic wave resonator according to an embodiment of the present disclosure;

FIG. 2 is a first preparation state schematic diagram of a film bulk acoustic wave resonator according to an embodiment of the present disclosure;

FIG. 3 is a second preparation state schematic diagram of a film bulk acoustic wave resonator according to an embodiment of the present disclosure;

FIG. 4 is a third preparation state schematic diagram of a film bulk acoustic wave resonator according to an embodiment of the present disclosure;

FIG. 5 is a fourth preparation state schematic diagram of a film bulk acoustic wave resonator according to an embodiment of the present disclosure;

FIG. 6 is a fifth preparation state schematic diagram of a film bulk acoustic wave resonator according to an embodiment of the present disclosure;

FIG. 7 is a sixth preparation state schematic diagram of a film bulk acoustic wave resonator according to an embodiment of the present disclosure;

FIG. 8 is a seventh preparation state schematic diagram of a film bulk acoustic wave resonator according to an embodiment of the present disclosure;

FIG. 9 is an eighth preparation state schematic diagram of a film bulk acoustic wave resonator according to an embodiment of the present disclosure;

FIG. 10 is a ninth preparation state schematic diagram of a film bulk acoustic wave resonator according to an embodiment of the present disclosure;

FIG. 11 is a tenth preparation state schematic diagram of a film bulk acoustic wave resonator according to an embodiment of the present disclosure;

FIG. 12 is an eleventh preparation state schematic diagram of a film bulk acoustic wave resonator according to an embodiment of the present disclosure;

FIG. 13 is a structural schematic diagram of a film bulk acoustic wave resonator according to an embodiment of the present disclosure;

FIG. 14 is a first preparation state schematic diagram of another film bulk acoustic wave resonator according to an embodiment of the present disclosure;

FIG. 15 is a structural schematic diagram of another film bulk acoustic wave resonator according to an embodiment of the present disclosure;

FIG. 16 is a first preparation state schematic diagram of another film bulk acoustic wave resonator according to an embodiment of the present disclosure;

FIG. 17 is a structural schematic diagram of another film bulk acoustic wave resonator according to an embodiment of the present disclosure;

FIG. 18 is a first preparation state schematic diagram of another film bulk acoustic wave resonator according to an embodiment of the present disclosure; and

FIG. 19 is a structural schematic diagram of another film bulk acoustic wave resonator according to an embodiment of the present disclosure;

### REFERENCE NUMERALS

1—substrate; 2—first sacrificial layer; 3—groove; 4—bottom electrode; 501—second sacrificial layer; 5—first-kind reflection cavity; 6—piezoelectric layer; 701—whole sacrificial layer; 702—third sacrificial layer; 7—fourth-kind reflection cavity; 8—third-kind reflection cavity; 9—top electrode; 10—second-kind reflection cavity; 11—first reflection cavity; 12—second reflection cavity; and 13—air gap.

### DETAILED DESCRIPTION OF THE EMBODIMENTS

Following described implementation expressions make those skilled in the art implement information necessary for implementations, and show an optimal mode for implementing the implementations. After the following description is read with reference to the drawings, those skilled in the art will know concepts of the present disclosure and realize applications of these concepts not specifically proposed in the present disclosure. It is to be understood that the concepts and the applications belong to the scope of the present disclosure and the attached claims.

It is to be understood that terms such as first and second may be used for describing various elements in the present disclosure but cannot limit the elements. The terms are only used for distinguishing one element from another element. For instance, a first element may be called a second element without departing from a scope of the present disclosure, and similarly, the second element may be called the first element. A term “and/or” used in the present disclosure includes any and all combinations of one or more of associated listed items

It is to be understood that when one element (e.g., a layer, an area or a substrate) is “arranged on another element” or “extends to another element”, the element may be directly arranged on the another element or directly extend to the another element, or there may be a middle element. On the contrary, when one element is “directly arranged on another element” or “directly extends to another element”, there is no middle element. Similarly, it is to be understood that when one element (e.g., a layer, an area or substrate) is “arranged above another element” or “extends above another element”, the element may be directly arranged above the another element or directly extend above the another element, or there may be a middle element. On the contrary, when one element is “directly arranged above another element” or “directly extends above another element”, there is no middle element. It is also to be understood that when one element is “connected” or “coupled” to another element, the element may be directly connected or coupled to the another element, or there may be a middle element. On the contrary, when one element is “directly connected” or “directly coupled” to another element, there is no middle element.

For instance, a term related to “below” or “above” or “upper portion” or “lower portion” or “horizontal” or “vertical” in the present disclosure may be used for describing a relationship between one element, layer or area and another element, layer or area, which is shown in the drawings. It is to be understood that these terms and the terms discussed above are intended to cover different orientations of an apparatus besides orientations described in the drawings.

The terms used in the present disclosure are merely used for describing purposes of specific implementations and are not intended to limit the present disclosure. As used in the present disclosure, unless clearly stated in the context, the singular form “a”, “one” and “the” is intended to similarly include a plural form. It is also to be understood that the term “include” used in the present disclosure indicates that there is the character, integer, step, operation, element and/or component, but it is possible that one or more other characters, integers, steps, operations, elements, components and/or sets of the above various terms exist or are added.

Unless additionally defined, all terms (including technological and scientific terms) used in the present disclosure have the same meaning usually understood by those of ordinary skill in the art of the present disclosure. It is also to be understood that the terms used in the present disclosure are explained to be consistent to those in the description and related fields in meaning rather than explained with ideal or too formal meaning, unless clearly defined in the present disclosure.

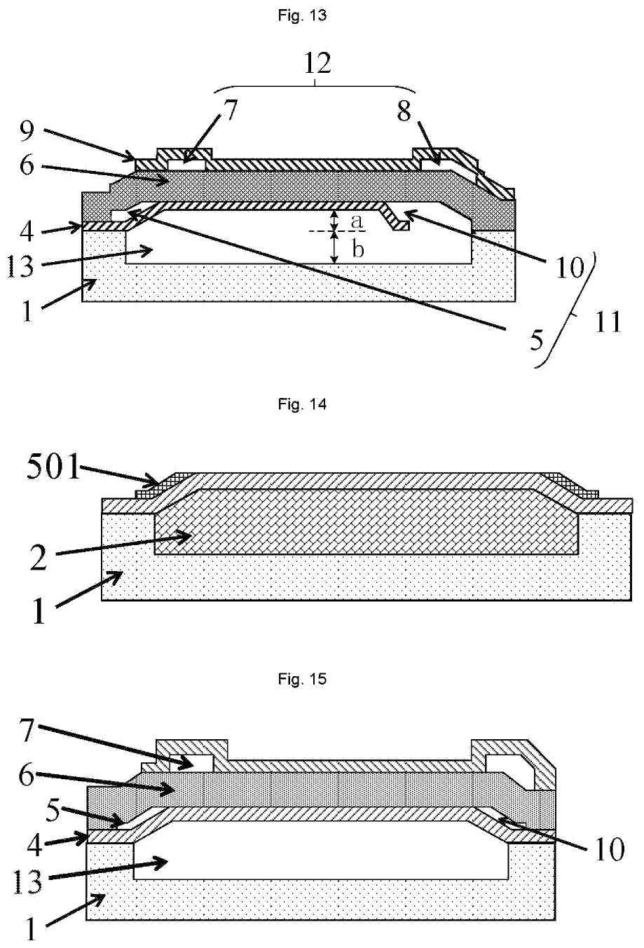

One aspect of an embodiment of the present disclosure, as shown in FIG. 13, provides a film bulk acoustic wave resonator, including a substrate 1 and a piezoelectric stack structure arranged on an upper surface of the substrate 1, where the piezoelectric stack structure includes a bottom electrode 4, a piezoelectric layer 6 and a top electrode 9 which are sequentially arranged on the upper surface of the substrate 1, and an overlap area of orthographic projections of the bottom electrode 4, the piezoelectric layer 6 and the top electrode 9 on the substrate 1 may serve as an effective working area of the film bulk acoustic wave resonator.

Please continue to refer to FIG. 13, the bottom electrode 4 is provided with a first arched part so that a first cavity can be formed between the bottom electrode 4 and the substrate 1 and located in the effective working area, and thus, the first cavity located below the piezoelectric stack structure can be utilized for reflecting acoustic waves to reduce acoustic wave leakage and losses and improve performance of the film bulk acoustic wave resonator.

On that basis, a first reflection cavity 11 may also be formed between the bottom electrode 4 and the piezoelectric layer 6 and distributed in a periphery of the effective working area, and thus, the first reflection cavity 11 is formed in the bottom electrode 4 and can be utilized for effectively reducing the transverse parasitic mode and acoustic wave leakage, and improving a quality factor of the film bulk acoustic wave resonator. In addition, the bottom electrode 4 is provided with the first arched part and the first reflection cavity 11 may be located in an oblique plane of a slope of the first arched part, and thus, when the first reflection cavity 11 reflects, by the slope, transverse acoustic waves, the transverse acoustic waves are reflected many times, thereby dissipating energy of the transverse acoustic waves, so as to further reduce the transverse parasitic mode, and improve the quality factor of the film bulk acoustic wave resonator. Namely, the function of arranging the first cavity is to: create a slope environment for the location of the first reflection cavity 11, so as to make the first reflection cavity matched with the slope by ensuring the basic performance of the resonator not to be influenced and without adopting a complex technology, and thus, the transverse acoustic waves can be reflected many times rather than directly reflected to the effective working area.

In the film bulk acoustic wave resonator, if the first cavity located below the piezoelectric stack structure has a good reflection effect, the cavity cannot be too thin and is required to have a certain thickness. But if the thickness of the first cavity is set in a thickness range in which the reflection effect is good, the first arched part of the bottom electrode 4 can be highly arched, and thus, after the piezoelectric layer 6 and the top electrode 9 are formed on the bottom electrode 4, the first arched part is high in stress and is likely to crack at a corner. Considering the situation, in the present disclosure, a second cavity communicating with the first cavity is formed below the surface of the substrate 1 so that an air gap 13 formed after communication of the first cavity and the second cavity can be in a proper thickness range; and meanwhile, the problem that the first arched part is likely to crack due to the too high stress can be solved, and reliability of the film bulk acoustic wave resonator is effectively guaranteed. In addition, the thickness of the substrate 1 is sufficiently utilized so as to effectively reduce the overall thickness of the film bulk acoustic wave resonator. The first cavity can be expanded into the substrate through the second cavity to utilize the sunk second cavity of the substrate 1 so that the air gap 13 can integrally reach the proper thickness, and thus, the thickness of the first cavity can be reduced, thereby reducing the stress exerted on the first arched part. The sunk second cavity of the substrate 1 is sufficiently utilized, and under the situation of ensuring the proper thickness of the air gap 13, the height of the first arched part is further reduced, and the stress of the first arched part is reduced.

Specifically, please refer to FIG. 13, the recessed second cavity is further formed in the upper surface of the substrate 1, in other words, the second cavity is located below the upper surface of the substrate 1, accordingly, the first cavity is located above the upper surface of the substrate 1, the second cavity communicates with the first cavity up and down to form the integral air gap 13, and thus, the thickness of the first cavity can be downwards expanded by the second cavity, the integral air gap 13 formed by both satisfies a certain thickness requirement so as to have a good reflection effect, and meanwhile defects caused by the too large arched height of the first arched part of the bottom electrode 4 can be overcome.

As shown in FIG. 13, to effectively reduce the stress of the first arched part, a thickness a of the first cavity may be less than a thickness b of the second cavity so that reliability and stability of the film bulk acoustic wave resonator can be guaranteed.

Please refer to FIG. 13, the thickness of the air gap 13, namely the sum of the thickness a of the first cavity and the thickness b of the second cavity is within 1 micron-5 microns, such as 1 micron, 2 microns, 3 microns, 4 microns and 5 microns, and thus, the thickness of the air gap 13 is in the proper thickness range, thereby guaranteeing the performance of the film bulk acoustic wave resonator.

As shown in FIG. 13, the first reflection cavity 11 includes a first-kind reflection cavity 5 and a second-kind reflection cavity 10, where the first-kind reflection cavity 5 and the second-kind reflection cavity 10 are both located in the slope of the first arched part so as to reflect the transverse acoustic waves; and by arranging the first-kind reflection cavity 5 and the second-kind reflection cavity 10 in the slope of the first arched part and changing the shape of the first arched part, the stress of the first arched part is released, and thus the problem that the first arched part is likely to crack due to the high stress is solved.

Please refer to FIG. 13, the first-kind reflection cavity 5 may not communicate with the air gap 13, and the second-kind reflection cavity 10 may communicate with the air gap 13. Please refer to FIG. 14 and FIG. 15, the first-kind reflection cavity 5 and the second-kind reflection cavity 10 may not communicate with the air gap 13. No limitation is made by the present disclosure, and reasonable selections can be made according to actual demands.

According to specific demands, the first reflection cavity 11 may be set into multiple forms. For example, in an embodiment: the first reflection cavity 11 is an annular cavity, at the time, the first-kind reflection cavity 5 communicates with the second-kind reflection cavity 10 to form the annular cavity, the annular cavity is annularly formed in the periphery of the effective working area of the film bulk acoustic wave resonator, and thus, the transverse acoustic waves can be effectively reflected by the first reflection cavity 11, thereby sufficiently reducing the transverse parasitic mode and the acoustic wave leakage, and improving the quality factor of the film bulk acoustic wave resonator. In another embodiment: there are a plurality of first reflection cavities 11 every two of which are not in communication, in addition, the plurality of first reflection cavities 11 are distributed in the periphery of the effective working area of the film bulk acoustic wave resonator, for example, although the first-kind reflection cavity 5 and the second-kind reflection cavity 10 are independent of each other without communication, the transverse parasitic mode and the acoustic wave leakage can be reduced, and the quality factor of the film bulk acoustic wave resonator is improved.

Please refer to FIG. 13, to further reduce the transverse parasitic mode and the acoustic wave leakage and effectively improve the quality factor of the film bulk acoustic wave resonator, a second reflection cavity 12 may also be formed between the piezoelectric layer 6 and the top electrode 9 and is disposed in the periphery of the effective working area of the film bulk acoustic wave resonator, and the second reflection cavity 12 formed in the top electrode 9 can reflect the transverse acoustic waves.

Specifically, as shown in FIG. 13, the bottom electrode 4 is provided with the first arched part, and thus, the piezoelectric layer 6 may be correspondingly provided with a second arched part stacked with the first arched part, and accordingly, the second arched part on the piezoelectric layer 6 also has a slope. The second reflection cavity 12 includes a third-kind reflection cavity 8, and when the third-kind reflection cavity 8 is arranged, the third-kind reflection cavity 8 may be disposed in the slope of the second arched part, and thus, by means of an oblique plane of the slope, when the third-kind reflection cavity 8 reflects the transverse acoustic waves, the transverse acoustic waves can be reflected many times so as to dissipate the energy of the transverse acoustic waves, thereby reducing the transverse parasitic mode.

To ensure the normal performance of the resonator, as shown in FIG. 13, the top electrode 9 is provided with a third arched part stacked with the second arched part, the first arched part, the second arched part and the third arched part all have flat tops parallel to the upper surface of the substrate 1, that is, the flat top of the first arched part and the flat top of the second arched part are in contact and are stacked, the flat top of the third arched part and the flat top of the second arched part are in contact and are stacked, and accordingly, the effective working area is constituted.

As shown in the FIG. 13, the second reflection cavity 12 may also include a fourth-kind reflection cavity 7 located in the flat top of second arched part, and accordingly, the fourth-kind reflection cavity 7 can directly reflect the transverse acoustic waves back to the effective working area.

A proportion that the first reflection cavity 11 distributed in the bottom electrode 4 occupies a perimeter of the effective working area is decided by a structural layout of the film bulk acoustic wave resonator. In a similar way, a proportion that the second reflection cavity 12 distributed in the top electrode 9 occupies the perimeter of the effective working area is decided by the structural layout of the film bulk acoustic wave resonator.

In different embodiments, an orthographic projection area of the first cavity in the substrate 1 and an orthographic projection area of the second cavity in the substrate 1 have different relationships. For example:

In an embodiment, as shown in FIG. 15, the orthographic projection area of the first cavity in the substrate 1 is equal to the orthographic projection area of the second cavity in the substrate 1.

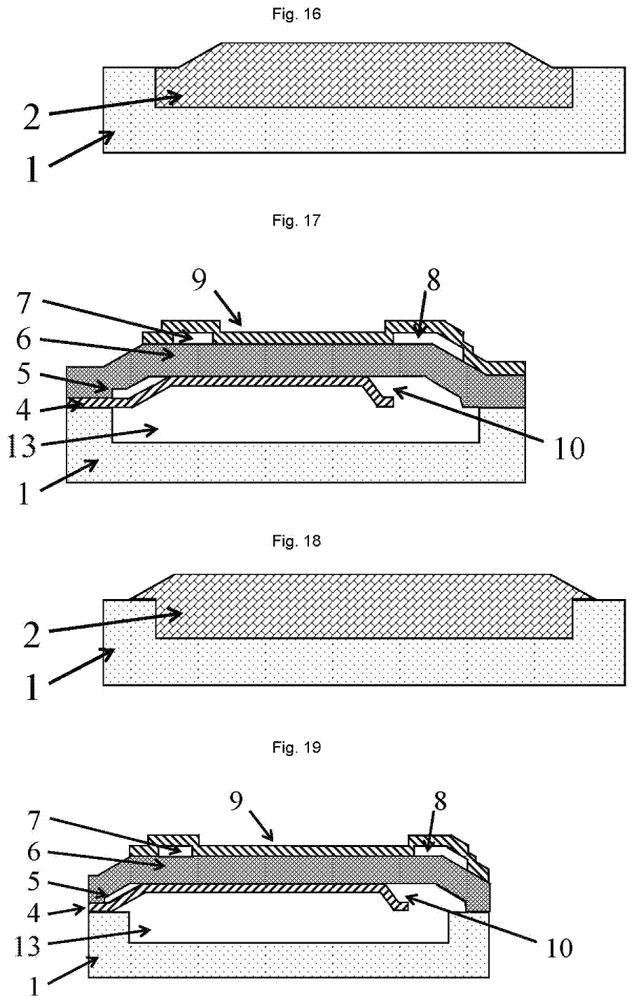

In an embodiment, as shown in FIG. 16 and FIG. 17, the orthographic projection area of the first cavity in the substrate 1 is less than the orthographic projection area of the second cavity in the substrate 1.

In an embodiment, as shown in FIG. 18 and FIG. 19, the orthographic projection area of the first cavity in the substrate 1 is greater than the orthographic projection area of the second cavity in the substrate 1.

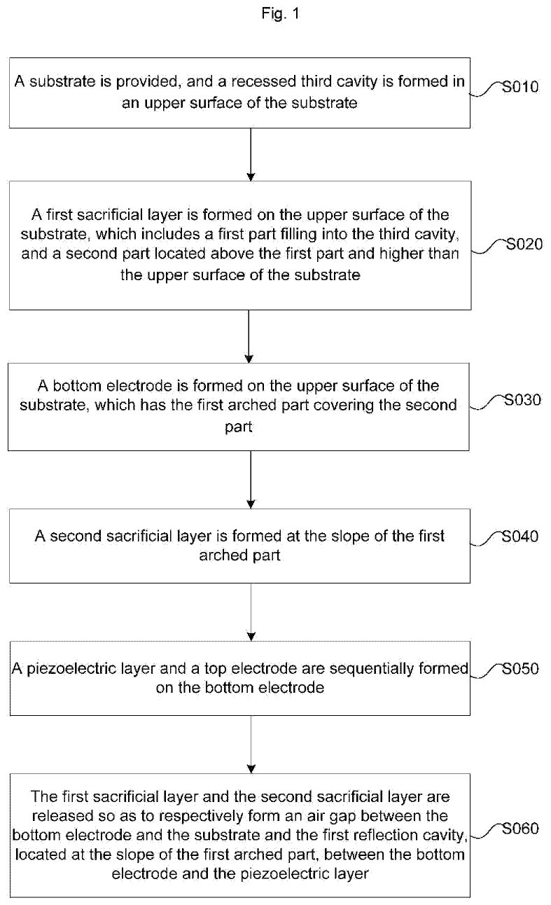

Another aspect of an embodiment of the present disclosure provides a method for preparing a film bulk acoustic wave resonator, and as shown in FIG. 1, including:

S010: A substrate is provided, and a recessed third cavity is formed in an upper surface of the substrate.

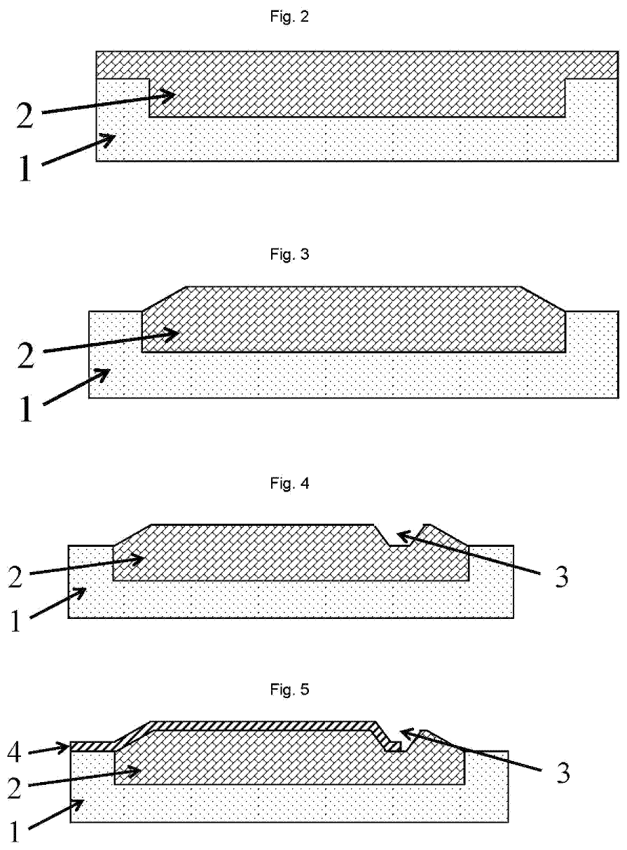

As shown in FIG. 2, the substrate 1 is provided, and the recessed third cavity is formed in the upper surface of the substrate 1 through etching, where the third cavity and the second cavity in the previous embodiment belong to the same cavity, and to facilitate understanding, the second cavity is described below.

S020: A first sacrificial layer is formed on the upper surface of the substrate, which includes a first part filling into the third cavity, and a second part located above the first part and higher than the upper surface of the substrate.

As shown in FIG. 2, a whole sacrificial layer is deposited on the upper surface, with the third cavity, of the substrate 1, the whole sacrificial layer completely fills into the second cavity and is higher than the upper surface of the substrate 1, and then an upper surface of the whole sacrificial layer is flattened, thereby forming the flat top of the later first arched part. Flattening may be a chemical-mechanical grinding process.

As shown in FIG. 3, the ground whole sacrificial layer is subjected to patterning treatment to form the first sacrificial layer 2, the first sacrificial layer 2 includes the first part filling into the second cavity, and the second part located above the first part, that is, the second part is higher than the upper surface of the substrate 1, the second part forms a stepped structure, that is, a top of the second part is a plane, and a side surface of the second part is a slope. The first part is used for forming the second cavity, and the second part is used for forming the first cavity.

S030: A bottom electrode is formed on the upper surface of the substrate, which has the first arched part covering the second part.

As shown in FIG. 4 and FIG. 5, metal is deposited on the upper surface of the substrate 1 and subjected to patterned, so that the bottom electrode 4 is formed; and the bottom electrode 4 covers the second part, higher than the upper surface of the substrate 1, of the first sacrificial layer 2, so that the bottom electrode 4 has the first arched part. The top of the second part is the plane, so that the part, attached to a top surface of the second part of the first sacrificial layer 2, of the first arched part is a plane, and accordingly, the flat top of the first arched part is formed.

S040: A second sacrificial layer is formed at the slope of the first arched part.

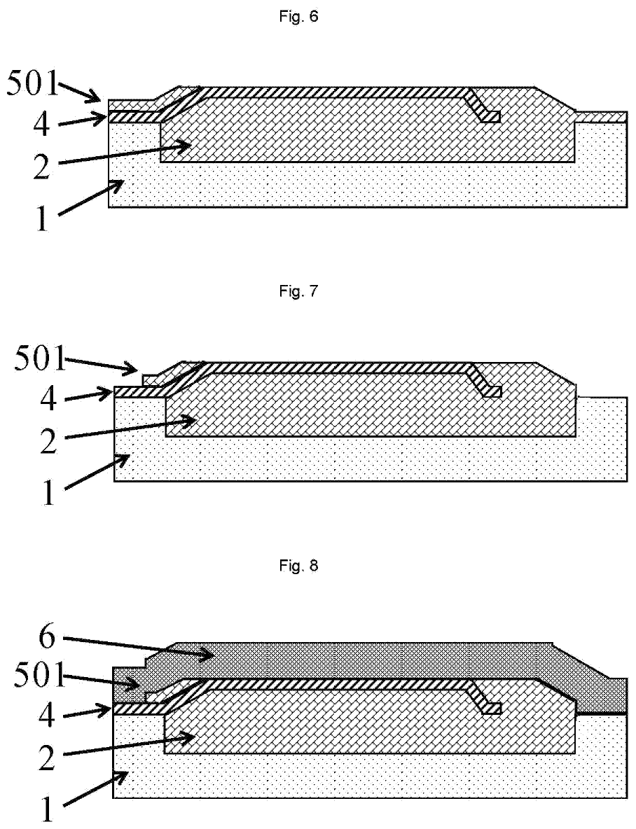

As shown in FIG. 6, a whole sacrificial layer is deposited on the bottom electrode 4, then, the sacrificial layer above the flat top of the first arched part of the bottom electrode 4 is removed by the grinding process, so that the flat top of the first arched part of the bottom electrode 4 is exposed, and meanwhile the sacrificial layer at the slope of the first arched part is reserved. As shown in FIG. 7, by patterning the sacrificial layer reserved at the slope of the first arched part, the remaining part serves as the second sacrificial layer 501 located at the slope of the first arched part, and the second sacrificial layer 501 is used for correspondingly forming a later first reflection cavity 11.

S050: A piezoelectric layer and a top electrode are sequentially formed on the bottom electrode.

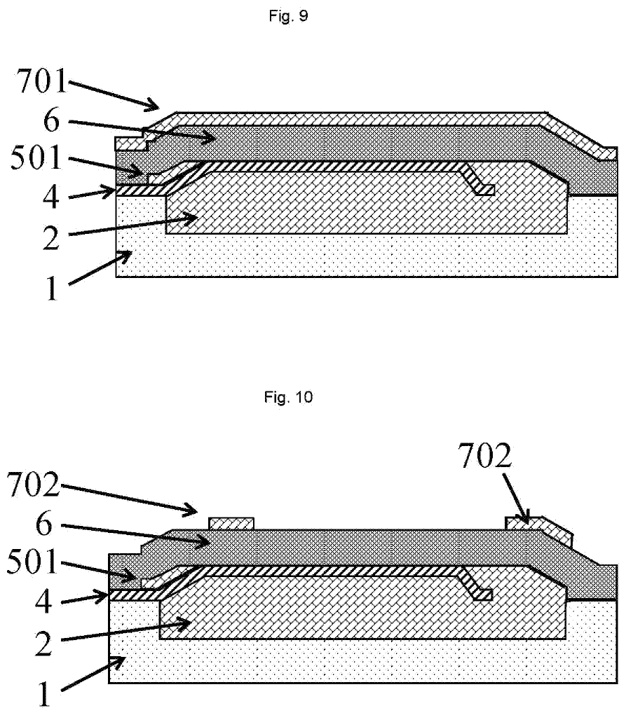

As shown in FIG. 8, the whole piezoelectric layer 6 is deposited on the bottom electrode 4, and covers the bottom electrode 4 and the second sacrificial layer 501. As shown in FIGS. 9 to 12, the top electrode 9 is formed on the piezoelectric layer 6 through deposition.

S060: The first sacrificial layer and the second sacrificial layer are released so as to respectively form an air gap between the bottom electrode and the substrate and the first reflection cavity, located at the slope of the first arched part, between the bottom electrode and the piezoelectric layer.

As shown in FIG. 13, the first reflection cavity 11 located in the slope of the first arched part is formed between the bottom electrode 4 and the piezoelectric layer 6 by releasing the second sacrificial layer 501, and the air gap 13 is formed between the bottom electrode 4 and the substrate 1 by releasing the first sacrificial layer 2. Correspondingly, the air gap 13 includes two parts, including a first part (the second cavity) located below the upper surface of the substrate 1, and a second part (the foregoing first cavity) located above the upper surface of the substrate 1.

When a second-kind reflection cavity 10 is required to communicate with the air gap 13, as shown in FIG. 4, the first sacrificial layer 2 can be etched to form a groove 3, and the groove 3 is located over the second cavity. As shown in FIG. 5, the bottom electrode 4 is deposited on the first sacrificial layer 2 with the groove 3, and one end of the bottom electrode 4 stretches into the groove 3, and namely extends into the groove 3; and as shown in FIG. 6, the second sacrificial layer 501 is deposited and then makes contact with the first sacrificial layer 2. As shown in FIG. 13, the second-kind reflection cavity 10 communicates with the lower air gap 13 by releasing the first sacrificial layer 2 and the second sacrificial layer 501.

When the second-kind reflection cavity 10 is required not to communicate with the air gap 13, as shown in FIG. 14, the bottom electrode 4 can be directly deposited on the first sacrificial layer 2, two ends of the bottom electrode 4 respectively extend to the surface of the substrate 1, so that the first sacrificial layer 2 and the second sacrificial layer 501 are separated by the bottom electrode 4, and accordingly, after the sacrificial layers are released, as shown in FIG. 15, the formed second-kind reflection cavity 10 does not communicate with the air gap 13.

As shown in FIG. 15, when an orthographic projection area of the first cavity on the substrate 1 is required to be equal to an orthographic projection area of the second cavity on the substrate 1, as shown in FIG. 14, an orthographic projection of the second part of the first sacrificial layer 2 on the substrate 1 can coincide with an orthographic projection of the second cavity on the substrate 1.

As shown in FIG. 17, when the orthographic projection area of the first cavity on the substrate 1 is required to be less than the orthographic projection area of the second cavity on the substrate 1, as shown in FIG. 16, the orthographic projection of the second part of the first sacrificial layer 2 on the substrate 1 can be less than the orthographic projection of the second cavity on the substrate 1.

As shown in FIG. 19, when the orthographic projection area of the first cavity on the substrate 1 is required to be greater than the orthographic projection area of the second cavity on the substrate 1, as shown in FIG. 18, the orthographic projection of the second part of the first sacrificial layer 2 on the substrate 1 can be greater than the orthographic projection of the second cavity on the substrate 1.

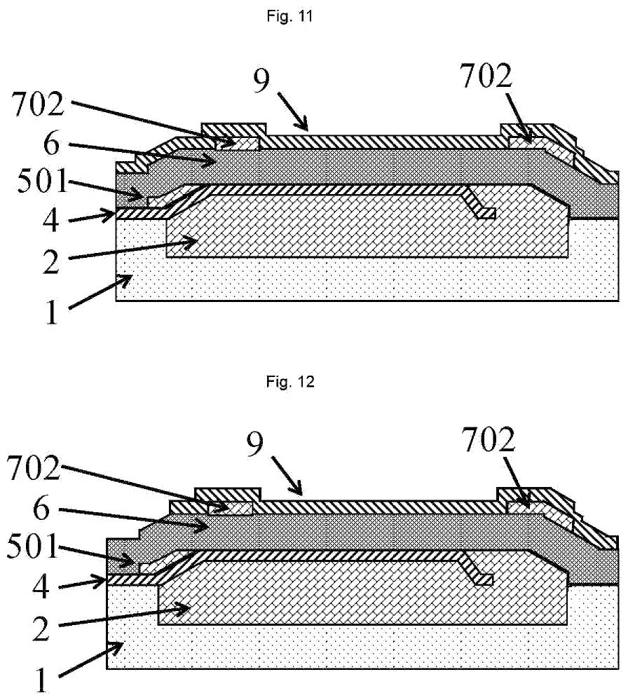

When the piezoelectric layer 6 and the top electrode 9 are sequentially formed on the bottom electrode 4, a second reflection cavity 12 can be formed there between. As shown in FIG. 9, a whole sacrificial layer 701 is deposited on the piezoelectric layer 6. As shown in FIG. 10, a third sacrificial layer 702 is formed after patterning and may be located at a flat top (corresponding to a fourth-kind reflection cavity 7) of a second arched part of the piezoelectric layer 6 and/or a slope (corresponding to a third-kind reflection cavity 8) of the second arched part. Then, as shown in FIG. 11, metal is deposited on the piezoelectric layer 6. As shown in FIG. 12, the metal is subjected to patterning to form the top electrode 9 covering the third sacrificial layer 702. As shown in FIG. 13, the third sacrificial layer 702 is released, so that the second reflection cavity 12 is formed between the piezoelectric layer 6 and the top electrode 9, and is located in a periphery of an effective working area of the film bulk acoustic wave resonator.

The above embodiments are merely preferred embodiments of the present disclosure and are not used for limiting the present disclosure, and the present disclosure can be variously modified and changed for those skilled in the art. Any modification, equivalent replacement, improvement, etc. made within the spirit and the principle of the present disclosure shall fall within the scope of protection of the present disclosure.

What is claimed is:

1. A film bulk acoustic wave resonator, comprising: a substrate and a bottom electrode, a piezoelectric layer and a top electrode which are located on an upper surface of the substrate, the bottom electrode being provided with a first arched part so as to form a first cavity between the first arched part and the substrate, and a first reflection cavity being formed between the bottom electrode and the piezoelectric layer and located in a slope of the first arched part, wherein a recessed second cavity is formed in the upper surface of the substrate and communicates with the first cavity to form an air gap, a thickness of the first cavity is less than a thickness of the second cavity.

2. The film bulk acoustic wave resonator according to claim 1, wherein the first reflection cavity is an annular cavity annularly formed in a periphery of an effective working area of the film bulk acoustic wave resonator; or the film bulk acoustic wave resonator comprises a plurality of first reflection cavities not communicating with one another, which are distributed in the periphery of the effective working area of the film bulk acoustic wave resonator.

3. The film bulk acoustic wave resonator according to claim 1, wherein the piezoelectric layer is provided with a second arched part stacked with the first arched part, and a second reflection cavity is formed between the second arched part and the top electrode, and located in the periphery of the effective working area of the film bulk acoustic wave resonator.

4. The film bulk acoustic wave resonator according to claim 3, wherein the second reflection cavity is located in a slope of the second arched part.

5. The film bulk acoustic wave resonator according to claim 3, wherein the top electrode is provided with a third arched part stacked with the second arched part, and all the first arched part, the second arched part and the third arched part are provided with flat tops parallel to the upper surface of the substrate.

6. The film bulk acoustic wave resonator according to claim 5, wherein the second reflection cavity is located in the flat top of the second arched part.

7. The film bulk acoustic wave resonator according to claim 1, wherein a thickness of the air gap ranges from 1 micron to 5 microns.

8. The film bulk acoustic wave resonator according to claim 2, wherein the first reflection cavity comprises a first-kind reflection cavity and a second-kind reflection cavity which are both located in the slope of the first arched part so as to reflect transverse acoustic waves.

9. The film bulk acoustic wave resonator according to claim 8, wherein the first-kind reflection cavity does not communicate with the air gap.

10. The film bulk acoustic wave resonator according to claim 9, wherein the second-kind reflection cavity communicates with the air gap.

11. The film bulk acoustic wave resonator according to claim 9, wherein the second-kind reflection cavity does not communicate with the air gap.

12. The film bulk acoustic wave resonator according to claim 3, wherein the second reflection cavity comprises a third-kind reflection cavity which is formed in the slope of the second arched part.

13. The film bulk acoustic wave resonator according to claim 12, wherein the top electrode is provided with a third arched part stacked with the second arched part, and all the first arched part, the second arched part and the third arched part are provided with flat tops parallel to the upper surface of the substrate.

14. The film bulk acoustic wave resonator according to claim 13, wherein the first arched part, the second arched part and the third arched part are sequentially stacked.

15. The film bulk acoustic wave resonator according to claim 13, wherein the second reflection cavity further comprises a fourth-kind reflection cavity which is located in the flat top of the second arched part.

16. A preparation method of a film bulk acoustic wave resonator, comprising:
providing a substrate, and forming a recessed third cavity in an upper surface of the substrate;
forming a first sacrificial layer on the upper surface of the substrate, comprising a first part filling into the third cavity, and a second part located above the first part and higher than the upper surface of the substrate;
forming a bottom electrode on the upper surface of the substrate, which has a first arched part covering the second part;
forming a second sacrificial layer at a slope of the first arched part;
sequentially forming a piezoelectric layer and a top electrode on the bottom electrode; and
releasing the first sacrificial layer and the second sacrificial layer so as to respectively form an air gap between the bottom electrode and the substrate and a first reflection cavity, located at the slope of the first arched part, between the bottom electrode and the piezoelectric layer,
wherein the air gap comprises the third cavity and a first cavity which is located on the upper surface of the substrate, the third cavity communicates with the first cavity, a thickness of the first cavity is less than a thickness of the third cavity.

17. The preparation method of the film bulk acoustic wave resonator according to claim 16, wherein sequentially forming the piezoelectric layer and the top electrode on the bottom electrode comprises:
forming a third sacrificial layer on the piezoelectric layer;
forming the top electrode covering the third sacrificial layer on the piezoelectric layer; and
releasing the third sacrificial layer so as to form a second reflection cavity between the piezoelectric layer and the top electrode, the second reflection cavity being located in a periphery of an effective working area of the film bulk acoustic wave resonator.

18. The preparation method of the film bulk acoustic wave resonator according to claim 17, wherein the first sacrificial layer is etched to form a groove, and the groove is located above the third cavity.

19. The preparation method of the film bulk acoustic wave resonator according to claim 18, wherein the first reflection cavity comprises a first-kind reflection cavity and a second-kind reflection cavity which are both located in the slope of the first arched part so as to reflect transverse acoustic waves.

20. The preparation method of the film bulk acoustic wave resonator according to claim 19, wherein the bottom electrode is deposited on the first sacrificial layer, and one end of the bottom electrode extends into the groove;
the second sacrificial layer is deposited and makes contact with the first sacrificial layer; and
the first sacrificial layer and the second sacrificial layer are released so that the second-kind reflection cavity can communicate with the lower air gap.
